(19) United States
(12) Patent Application Publication
(10) Pub. No.: US 2024/0304588 A1
(43) Pub. Date: Sep. 12, 2024

(54) SEMICONDUCTOR MODULE

(71) Applicant: FUJI ELECTRIC CO., LTD., Kawasaki-shi (JP)

(72) Inventor: Akio YAMANO, Frankfurt am Main (DE)

(73) Assignee: FUJI ELECTRIC CO., LTD., Kawasaki-shi (JP)

(21) Appl. No.: 18/420,282

(22) Filed: Jan. 23, 2024

(30) Foreign Application Priority Data
Mar. 6, 2023 (JP) 2023-033883

(51) Int. Cl. H01L 23/00; H01L 23/31; H01L 23/498; H01L 25/065

(52) U.S. Cl. CPC H01L 24/45; H01L 23/3121; H01L 23/49838; H01L 24/48; H01L 24/49; H01L 25/0655; H01L 2224/45012; H01L 2224/48137; H01L 2224/48177; H01L 2224/49175; H01L 2924/12032; H01L 2924/13055; H01L 2924/13091

(57) ABSTRACT

A semiconductor module includes a first semiconductor chip having a first top surface on which a first control electrode and a first main electrode are disposed, a second semiconductor chip having a second top surface on which a second control electrode and a second main electrode are disposed, and a plate-shaped wiring member facing, and being electrically connected to, the first and second main electrodes, in which the first semiconductor chip is spaced apart from the second semiconductor chip in a first direction in plan view, the first top surface has a first-peripheral edge in the first direction, the first control electrode is interposed between the first-peripheral edge and the first main electrode, the second top surface has a second-peripheral edge in a second direction opposite to the first direction, and the second control electrode is interposed between the second-peripheral edge and the second main electrode.

### CROSS REFERENCE TO RELATED APPLICATION

This Application is based on, and claims priority from, Japanese Patent Application No. 2023-033883, filed on Mar. 6, 2023, the entire contents of which are incorporated herein by reference.

### BACKGROUND

### Technical Field

This disclosure relates to a semiconductor module.

### Related Art

Semiconductor modules have been proposed that include a plurality of semiconductor chips including, for example, an insulated gate bipolar transistor (IGBT) or a metal oxide semiconductor field effect transistor (MOSFET) as disclosed in (1) Japanese Patent Application Laid-Open Publication No. 2021-072293, (2) Japanese Patent Application Laid-Open Publication No. 2018-061066, (3) Japanese Patent Application Laid-Open Publication No. 2006-202885, (4) Japanese Patent Application Laid-Open Publication No. 2015-170731, and (5) WO 2018/185974. In general, the plurality of semiconductor chips includes a plurality of main electrodes electrically connected to a conductor such as a conductive pattern via multiple wires. In this configuration, the multiple wires are not equal to each other in length. Thus, the multiple wires are not equal to each other in electrical resistance. As a result, when a current flows through each of the multiple wires, the multiple wires may be not equal to each other in amount of heat that is generated. In other words, one or some of the multiple wires may generate more heat compared to the others.

### SUMMARY

An object of one aspect according to this disclosure is to reduce difference between electrical resistance values of current paths for semiconductor chips.

A semiconductor module according to one aspect of the present disclosure includes: a first semiconductor chip having a first top surface on which a first control electrode and a first main electrode are disposed; a second semiconductor chip having a second top surface on which a second control electrode and a second main electrode are disposed; and a plate-shaped wiring member facing the first main electrode and the second main electrode and being electrically connected to the first main electrode and to the second main electrode, in which the first semiconductor chip is spaced apart from the second semiconductor chip in a first direction in plan view, the first top surface has a first peripheral edge in the first direction, the first control electrode is interposed between the first peripheral edge of the first top surface and the first main electrode, the second top surface has a second peripheral edge in a second direction opposite to the first direction, and the second control electrode is interposed between the second peripheral edge of the second top surface and the second main electrode.

### BRIEF DESCRIPTION OF THE DRAWINGS

FIG. 1 is a plan view of a semiconductor module according to a first embodiment.

FIG. 2 is a cross section taken along line II-II in FIG. 1.

FIG. 3 is a cross section taken along line III-III in FIG. 1.

FIG. 4 is a plan view of the semiconductor module from which a wiring member is omitted.

FIG. 5 is a plan view of a semiconductor module according to a comparative example.

FIG. 6 is a plan view of the semiconductor module according to a second embodiment.

FIG. 7 is a cross section taken along line VI-VII in FIG. 6.

FIG. 8 is a plan view of the semiconductor module according to a third embodiment.

FIG. 9 is a plan view of a semiconductor unit according to the third embodiment.

FIG. 10 is a plan view of the semiconductor module according to a modification.

FIG. 11 is a cross section of the semiconductor module according to another modification.

FIG. 12 is a cross section of the semiconductor module according to yet another modification.

FIG. 13 is a cross section of the semiconductor module according to yet another modification.

FIG. 14 is a cross section of the semiconductor module according to yet another modification.

### DESCRIPTION OF EMBODIMENTS

Embodiments according to the present disclosure will now be described with reference to the accompanying drawings. In each drawing, dimensions and scales of elements may differ from those of actual products. In addition, each embodiment described below is an exemplary embodiment assumed in a case in which the present disclosure is implemented. Thus, the scope of the present disclosure is not limited to the embodiments described below.

### A: First Embodiment

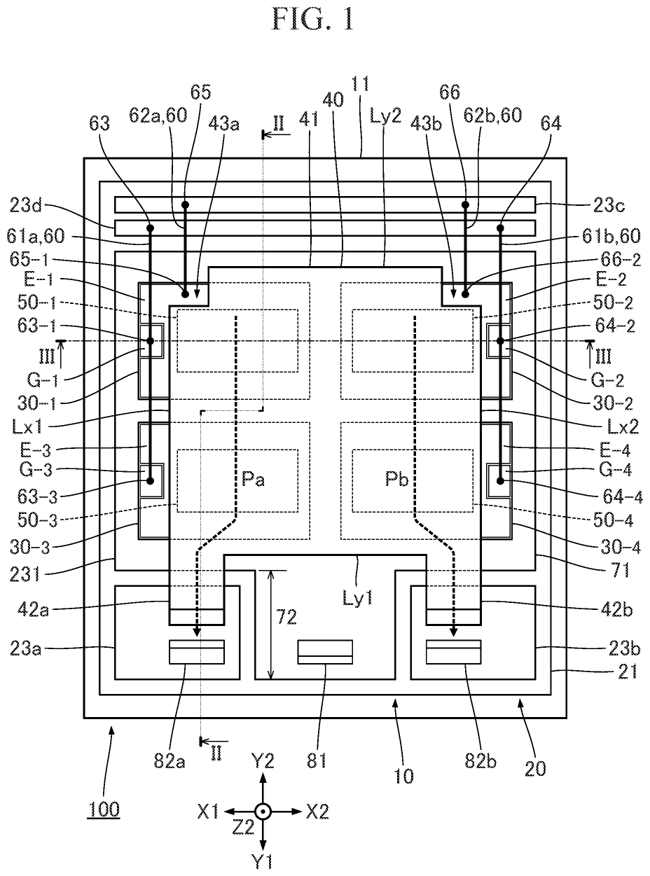

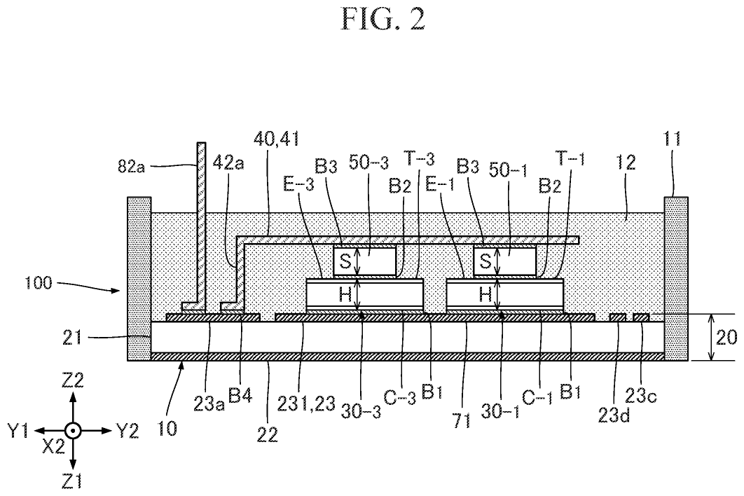

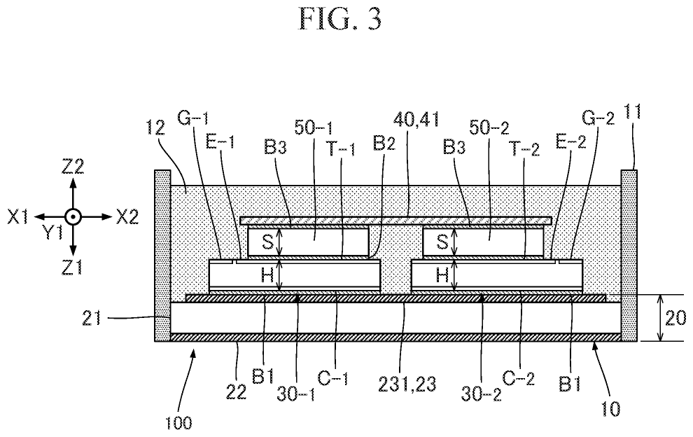

FIG. 1 is a plan view of a semiconductor module 100 according to a first embodiment. FIG. 2 is a cross section taken along line II-II in FIG. 1. FIG. 3 is a cross section take along line I-II in FIG. 1. In the first embodiment, the semiconductor module 100 is a power semiconductor device that constitutes a power conversion device such as an inverter circuit.

In the following description, an X-axis, a Y-axis, and a Z-axis are defined that are perpendicular to one another. A direction along the X-axis is referred to as an X1 direction, and a direction opposite to the X1 direction is referred to as an X2 direction. The X1 direction is an example of a “first direction.” The X2 direction is an example of a “second direction.” A direction along the Y-axis is referred to as a Y1 direction, and a direction opposite to the Y1 direction is referred to as a Y2 direction. The Y1 direction is an example of a “third direction.” A direction along the Z-axis is referred to as a Z1 direction, and a direction opposite to the Z1 direction is referred to as a Z2 direction. In the following description, viewing an element, which is freely selected from the semiconductor module 100, along a direction of the Z-axis (Z1 direction or Z2 direction) is referred to as a “plan view.”

In actual use, the semiconductor module 100 can be disposed in a freely selected direction. However, for convenience in the following description, the Z1 direction is assumed to be downward and the Z2 direction is assumed to be upward. Thus, a surface, which faces in the Z1 direction, of an element freely selected from the semiconductor module 100 may be referred to as a “lower surface” and a surface, which faces in the Z2 direction, of the element may be referred to as an “upper surface.”

As shown in FIG. 1 to FIG. 3, the semiconductor module 100 includes a semiconductor unit 10, a housing 11, and an encapsulant 12. In FIG. 1, the encapsulant 12 is omitted for convenience.

The housing 11 accommodates the semiconductor unit 10 and the encapsulant 12. The housing 11 may be referred to as a case. The housing 11 is made of an insulating resin material such as a polyphenylene sulfide (PPS) resin material, a polybutylene terephthalate (PBT) resin material, a polybutylene succinate (PBS) resin material, a polyamide (PA) resin material, or an acrylonitrile-butadiene-styrene (ABS) resin material, etc.

The encapsulant 12 is made of an insulating material that is filled in an internal space of the housing 11. The encapsulant 12 encapsulates the semiconductor unit 10. For example, the encapsulant 12 is made of a resin material such as an epoxy resin material, a silicone resin material, or a polyamide resin material, etc. The encapsulant 12 may include fillers that are made of a silicon oxide material or that are made of an aluminum oxide material, for example.

The semiconductor unit 10 includes a mounting substrate 20, four semiconductor chips 30-1 to 30-4, a wiring member 40, four conductive spacers 50-1 to 50-4, and a plurality of wires 60. The four semiconductor chips 30-1 to 30-4, the wiring member 40, the four conductive spacers 50-1 to 50-4, and the plurality of wires 60 are encapsulated by the encapsulant 12.

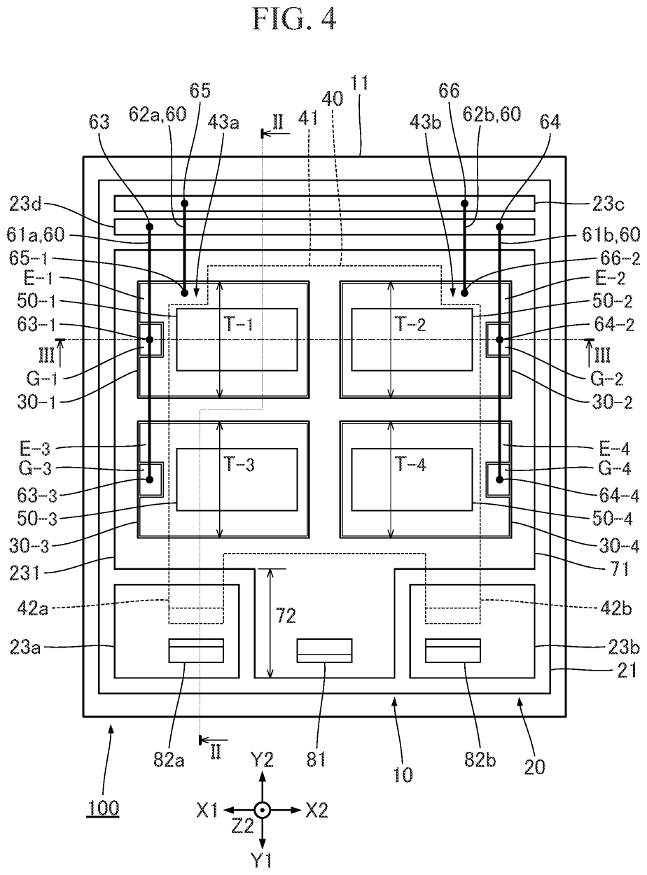

FIG. 4 is a plan view of the semiconductor module 100. In FIG. 4, an outer shape of the wiring member 40 is shown by a dashed line. In FIG. 4, the line II-II corresponding to the cross section shown in FIG. 2 and the line II-III corresponding to the cross section shown in FIG. 3 are shown as in FIG. 1. In FIG. 4, the encapsulant 12 is omitted for convenience.

The mounting substrate 20 is a wiring substrate on which the four semiconductor chips 30-1 to 30-4 are disposed. For example, the mounting substrate 20 may be a substrate such as a direct copper bonding (DCB) substrate, an active metal brazing (AMB) substrate, or an insulated metal substrate (IMS), etc.

As shown in FIG. 2 and FIG. 3, the mounting substrate 20 includes a stack of an insulating substrate 21, a metallic layer 22, and a plurality of conductive patterns 23 (231, 23a, 23b, 23c, and 23d). The insulating substrate 21 is a rectangular plate-shaped member made of an insulating material. The insulating substrate 21 is made of a ceramic material such as aluminum oxide, aluminum nitride, or silicon nitride, etc. Alternatively, the insulating substrate 21 may be made of a resin material such as an epoxy resin material.

The metallic layer 22 is a rectangular plate-shaped member fixed to a lower surface of the insulating substrate 21. The metallic layer 22 is made of, for example, a metallic material with high thermal conductivity such as a copper material, or an aluminum material, etc. The metallic layer 22 transfers heat generated by the semiconductor chips 30 to a heat radiating plate (not shown). The heat radiating plate is a plate-shaped member fixed to the metallic layer 22. The heat radiating plate is made of a conductive material such as an aluminum material or a copper material, etc.

Each of the plurality of conductive patterns 23 (231, 23a, 23b, 23c, and 23d) is a thin plate-shaped conductor disposed on an upper surface of the insulating substrate 21. Each of the plurality of conductive patterns 23 is made of a low-resistance conductive material such as a copper material or an alloy of copper, etc. Each of the plurality of conductive patterns 23 has a surface parallel to an X-Y plane.

As shown in FIG. 1 and FIG. 4, the conductive pattern 231 includes a mounting portion 71 and a connection portion 72. In plan view, the mounting portion 71 is substantially rectangular. The mounting portion 71 has a peripheral edge in the Y1 direction. The connection portion 72 protrudes in the Y1 direction from the middle of the peripheral edge of the mounting portion 71. The connection portion 72 is fixed to a connection terminal 81. The connection terminal 81 is a terminal for electrically connecting the semiconductor unit 10 to an external device.

The conductive pattern 23a is spaced apart from the connection portion 72 in the X1 direction. The conductive pattern 23b is spaced apart from the connection portion 72 in the X2 direction. The conductive pattern 23a is fixed to a connection terminal 82a. The conductive pattern 23b is fixed to a connection terminal 82b. The connection terminal 82a and the connection terminal 82b are each a terminal for electrically connecting the semiconductor unit 10 to the external device.

The conductive pattern 23c is spaced apart from the conductive pattern 231 in the Y2 direction. The conductive pattern 23d is interposed between the conductive pattern 231 and the conductive pattern 23c. The conductive pattern 23c and the conductive pattern 23d each extend linearly in a direction of the X-axis.

Each of the four semiconductor chips 30-1 to 30-4 is a power semiconductor element disposed on the mounting substrate 20. Each of the four semiconductor chips 30-1 to 30-4 may be referred to as a “semiconductor chip 30-n” (n=1 to 4). The semiconductor chip 30-n is fixed to the mounting substrate 20. In the first embodiment, the four semiconductor chips 30-1 to 30-4 are fixed to the conductive pattern 231 (the mounting portion 71).

The semiconductor chip 30-n is a reverse conducting insulated gate bipolar transistor (RC-IGBT) that includes both an insulated gate bipolar transistor (IGBT) and a freewheeling diode (FWD). The four semiconductor chips 30-1 to 30-4 are of the same type. Thus, as shown in FIG. 2 and FIG. 3, heights H of the four semiconductor chips 30-1 to 30-4 are equal to each other. The height H of the semiconductor chip 30-n is 50 μm or more and 400 μm or less, for example.

The semiconductor chip 30-n includes a main electrode C-n, a main electrode E-n, and a control electrode G-n. The main electrode C-n and the main electrode E-n are electrodes that receive and output a current as a control target. The main electrode C-n is a collector electrode that constitutes a lower surface of the semiconductor chip 30-n. The main electrode C-n is fixed to the conductive pattern 231 by a conductive joining material B1 such as a solder material or a sintered material, etc.

The main electrode E-n is an emitter electrode that constitutes a top surface T-n of the semiconductor chip 30-n. The control electrode G-n is a gate electrode to which a control voltage is applied for control to turn the semiconductor chip 30-n on and off. The control electrode G-n and the main electrode E-n constitutes the top surface T-n of the semiconductor chip 30-n. As will be understood from the above description, the top T-n of the semiconductor chip 30-n is provided with the main electrode E-n and the control electrode G-n. The top surface T-n is an example of an “n-th top surface.”

As shown in FIG. 1 and FIG. 4, in plan view, the semiconductor chip 30-1 is spaced apart from the semiconductor chip 30-2 in the X1 direction. In plan view, the semiconductor chip 30-3 is spaced apart from the semiconductor chip 30-1 in the Y1 direction. In plan view, the semiconductor chip 30-4 is spaced apart from the semiconductor chip 30-2 in the Y1 direction. As will be understood from the above description, the four semiconductor chips 30-1 to 30-4 are arranged to be a matrix that has two rows along the X-axis and two columns along the Y-axis. The semiconductor chip 30-n is an example of an “n-th semiconductor chip.” The main electrode E-n is an example of an “n-th main electrode.” The control electrode G-n is an example of an “n-th control electrode.”

As shown in FIG. 4, the semiconductor chip 30-1 has a top surface T-1, a control electrode G-1, and a main electrode E-1. The top surface T-1 has a first peripheral edge in the X1 direction. In plan view, the control electrode G-1 is interposed between the first peripheral edge of the top surface T-1 and the main electrode E-1. In other words, the top surface T-1 has a region that is apart from a center of the top surface T-1 in the X1 direction, and the control electrode G-1 is disposed on the region of the top surface T-1. Thus, in plan view, the main electrode E-1 is interposed between the control electrode G-1 and the semiconductor chip 30-2. The semiconductor chip 30-3 has a top surface T-3, a control electrode G-3, and a main electrode E-3. The top surface T-3 has a third peripheral edge in the X1 direction. In plan view, the control electrode G-3 is interposed between the third peripheral edge of the top surface T-3 and the main electrode E-3. The control electrode G-1 and the control electrode G-3 are aligned with, and are apart from, each other in a direction of the Y-axis.

The semiconductor chip 30-2 has a top surface T-2, a control electrode G-2, and a main electrode E-2. The top surface T-2 has a second peripheral edge in the X2 direction. In plan view, the control electrode G-2 is interposed between the second peripheral edge of the top surface T-2 and the main electrode E-2. In other words, the top surface T-2 has a region that is apart from a center of the top surface T-2 in the X2 direction, and the control electrode G-2 is disposed on the region of the top surface T-2. Thus, in plan view, the main electrode E-2 is interposed between the control electrode G-2 and the semiconductor chip 30-1. The semiconductor chip 30-4 has a top surface T-4, a control electrode G-4, and a main electrode E-4. The top surface T-4 has a fourth peripheral edge in the X2 direction. In plan view, the control electrode G-4 is interposed between the fourth peripheral edge of the top surface T-4 and the main electrode E-4. The control electrode G-2 and the control electrode G-4 are aligned with, and are apart from, each other in the direction of the Y-axis.

As will be understood from the above description, the semiconductor chip 30-1 and the semiconductor chip 30-2 are aligned with each other to be a first row. The control electrode G-1 is disposed on one end of the first row. The control electrode G-2 is disposed on the other end of the first row. The semiconductor chip 30-3 and the semiconductor chip 30-4 are aligned with each other to be a second row. The control electrode G-3 is disposed on one end of the second row. The control electrode G-4 is disposed on the other end of the second row.

In FIG. 1, the wiring member 40 is a plate-shaped conductor that is electrically connected to the respective semiconductor chips 30. The wiring member 40 is made of a low-resistance conductive material such as a copper material or an alloy of copper, etc. The wiring member 40 has a thickness of about 0.3 mm, for example. In the first embodiment, the wiring member 40 is a structure that includes a cover 41, a leg 42a, and a leg 42b that are integrally formed together with each other. The wiring member 40 is formed by bending a metallic plate, for example. The wiring member 40 may be referred to as a lead frame.

The cover 41 is a plate-shaped portion that is parallel to the X-Y plane. The cover 41 faces the mounting substrate 20 across a space. In plan view, the cover 41 overlaps the four semiconductor chips 30-1 to 30-4. In other words, the four semiconductor chips 30-1 to 30-4 are interposed between the cover 41 of the wiring member 40 and the mounting substrate 20. Specifically, the wiring member 40 faces the main electrode E of each of the four semiconductor chips 30-1 to 30-4.

As shown in FIG. 1 to FIG. 3, a conductive spacer 50-n is interposed between the semiconductor chip 30-n and the cover 41. The conductive spacer 50-n is a plate-shaped conductor. In plan view, the conductive spacer 50-n is substantially rectangular. The conductive spacer 50-n is interposed between a lower surface of the cover 41 and the main electrode E-n of the semiconductor chip 30-n. The conductive spacer 50-n is an example of an “n-th conductive spacer.”

As shown in FIG. 1, the conductive spacer 50-n is smaller in size than the main electrode E-n. In plan view, the conductive spacer 50-n is disposed inside the main electrode E-n. In other words, the entire conductive spacer 50-n is disposed within a region defined by a peripheral edge of the main electrode E-n. Four conductive spacers 50-1 to 50-4 have the same planar shape.

As shown in FIG. 2 and FIG. 3, the conductive spacer 50-n has a thickness S that is set dependent on a distance between the cover 41 and the semiconductor chip 30-n. As described above, the respective heights H of the four semiconductor chips 30-1 to 30-4 are equal to each other. As a result, the four semiconductor chips 30-1 to 30-4 are equal to each other in distance between the cover 41 and the main electrode E. Thus, the respective thicknesses S of the four conductive spacers 50-1 to 50-4 are equal to each other. The thickness S of the conductive spacer 50-n is 0.2 mm or more and 1.0 mm or less, for example.

As described above, the four conductive spacers 50-1 to 50-4 are equal to each other in size (planar shape and thickness S). Thus, there is no need to distinguish between the conductive spacers 50-1 to 50-4 in a process of manufacturing the semiconductor unit 10. In other words, the first embodiment can simplify control of the conductive spacers 50-1 to 50-4, thereby reducing manufacturing costs of the semiconductor unit 10.

Regarding the height H of each of the semiconductor chips 30 or regarding the size (for example, thickness S) of each of the conductive spacers 50, dimension A and dimension B being equal to each other mean not only the dimension A and the dimension B being completely equal to each other, but also the dimension A and the dimension B being substantially equal to each other. “Dimension A and dimension B being substantially equal to each other” may mean a case in which the dimension A and the dimension B are different from each other and the difference between the dimension A and the dimension B is within a range of a manufacturing error. For example, if an error between dimension A and dimension B is within a range of a manufacturing error between −10 percent to +10 percent (more preferably −5 percent to +5 percent), the dimension A and the dimension B are interpreted as being equal to each other.

The conductive spacer 50-n has a lower surface that is fixed by a joining material B2 such as a solder material or a sintered material to the main electrode E-n of the semiconductor chip 30-n. The conductive spacer 50-n has an upper surface that is fixed by a joining material B3 such as a solder material or a sintered material to the wiring member 40. Thus, the wiring member 40 is electrically connected to each of the main electrodes E. In other words, the main electrodes E of the four semiconductor chips 30-1 to 30-4 are electrically connected to the wiring member 40 via the conductive spacers 50.

As shown in FIG. 1, the cover 41 is a substantially rectangular portion of the wiring member 40. The cover 41 is defined by a peripheral edge Lx1, a peripheral edge Lx2, a peripheral edge Ly1, and a peripheral edge Ly2. The peripheral edge Lx1 is an edge of the cover 41 along the Y-axis. The peripheral edge Lx1 is apart from the peripheral edge Lx2 in the X1 direction. The peripheral edge Lx2 is another edge of the cover 41 along the Y-axis. The peripheral edge Lx2 is apart from the peripheral edge Lx1 in the X2 direction. The peripheral edge Ly1 is an edge of the cover 41 along the X-axis. The peripheral edge Ly1 is apart from the peripheral edge Ly2 in the Y1 direction. The peripheral edge Ly2 is another edge of the cover 41 along the X-axis. The peripheral edge Ly2 is apart from the peripheral edge Ly1 in the Y2 direction. In plan view, the connection portion 72 of the conductive pattern 231 protrudes from the peripheral edge Ly1 of the wiring member 40 in the Y1 direction.

In plan view, the control electrode G-1 of the semiconductor chip 30-1 and the control electrode G-3 of the semiconductor chip 30-3 are apart from the peripheral edge Lx1 of the cover 41 in the X1 direction. Specifically, in plan view, the control electrode G-1 and the control electrode G-3 are disposed outside the wiring member 40. In plan view, the control electrode G-1 and the control electrode G-3 are aligned with each other along the peripheral edge Lx1 in the direction of the Y-axis. In other words, in plan view, the control electrode G-1 and the control electrode G-3 are separate from the wiring member 40.

In plan view, the control electrode G-2 of the semiconductor chip 30-2 and the control electrode G-4 of the semiconductor chip 30-4 are apart from the peripheral edge Lx2 of the cover 41 in the X2 direction. Specifically, in plan view, the control electrode G-2 and the control electrode G-4 are disposed outside the wiring member 40. In plan view, the control electrode G-2 and the control electrode G-4 are aligned with each other along the peripheral edge Lx2 in the direction of the Y-axis. In other words, in plan view, the control electrode G-2 and the control electrode G-4 are separate from the wiring member 40. As will be understood from the above description, each of the control electrodes G of the four semiconductor chips 30-1 to 30-4 is separate from the wiring member 40 in plan view.

The peripheral edge Ly2 has one end portion in the X1 direction. The one end portion of the peripheral edge Ly2 has a notch 43a. The peripheral edge Ly2 has the other end portion in the X2 direction. The other end portion of the peripheral edge Ly2 has a notch 43b. The notch 43a and the notch 43b are each a rectangular recess that is recessed from the peripheral edge Ly2 in the Y1 direction. In other words, the notch 43a is at a portion of the cover 41 in which the peripheral edge Lx1 and the peripheral edge Ly2 intersect with each other. The notch 43b is at a portion of the cover 41 in which the peripheral edge Lx2 and the peripheral edge Ly2 intersect with each other. The notch 43a is an example of a “first notch.” The notch 43b is an example of a “second notch.”

The leg 42a of the wiring member 40 protrudes from the cover 41 toward the conductive pattern 23a. The peripheral edge Ly1 of the cover 41 has one end portion in the X1 direction. The leg 42a is bent in the Z1 direction toward the conductive pattern 23a from the one end portion of the peripheral edge Ly1. As shown in FIG. 2, the leg 42a has an end that is fixed by a joining material B4 such as a solder material or a sintered material to the conductive pattern 23a. As shown in FIG. 1, the leg 42b of the wiring member 40 protrudes from the cover 41 toward the conductive pattern 23b. The peripheral edge Lyl of the cover 41 has the other end portion in the X2 direction. The leg 42b is bent in the Z1 direction toward the conductive pattern 23b from the other end portion of the peripheral edge Ly1. The leg 42b has an end that is fixed by a joining material B4 such as a solder material or a sintered material to the conductive pattern 23b.

As will be understood from the above description, an end of the wiring member 40 in the Y1 direction (the end of the leg 42a and the end of the leg 42b) are fixed to the conductive pattern 23a and the conductive pattern 23b. In the above configuration, a current having passed through the semiconductor chips 30 from the conductive pattern 231 flows through the wiring member 40 in the Y1 direction and is then supplied to the conductive pattern 23a and the conductive pattern 23b from the end of the wiring member 40 in the Y1 direction. Specifically, as shown in FIG. 1, a current path Pa and a current path Pb are formed. The current path Pa is a path from the semiconductor chip 30-1 and the semiconductor chip 30-3 to the conductive pattern 23a via the leg 42a of the wiring member 40. The current path Pb is a path from the semiconductor chip 30-2 and the semiconductor chip 30-4 to the conductive pattern 23b via the leg 42b of the wiring member 40. The conductive pattern 23a and the conductive pattern 23b are each an example of a “second conductive pattern.”

The plurality of wires 60 are linear conductors for electrically connecting the semiconductor chips 30 and the conductive pattern 23 to each other. Each of the plurality of wires 60 is made of a low-resistance conductive material such as a copper material or an alloy of copper, etc. Each of the plurality of wires 60 is fixed by ultrasonic bonding, for example. Each of the plurality of wires 60 has a diameter of 300 μm or more and 500 μm or less, for example. In FIG. 2 and FIG. 3, the plurality of wires 60 is omitted for convenience. In the first embodiment, the plurality of wires 60 includes a control wire 61a, a control wire 61b, an auxiliary wire 62a, and an auxiliary wire 62b.

The control wire 61a is a wire 60 for electrically connecting the control electrode G-1 of the semiconductor chip 30-1 and the control electrode G-3 of the semiconductor chip 30-3 to the conductive pattern 23d. The control wire 61a is fixed to the control electrode G-1 and the control electrode G-3. The control wire 61a is apart from the peripheral edge Lx1 of the wiring member 40 in the X1 direction. The control wire 61a extends along the peripheral edge Lx1 in the direction of the Y-axis. In other words, in plan view, the control wire 61a is separate from the wiring member 40.

The control wire 61a has a connector 63-3 that is one end of the control wire 61a in the Y1 direction. The connector 63-3 is fixed to the control electrode G-3. The control wire 61a has a connector 63 that is the other end of the control wire 61a. The connector 63 is fixed to the conductive pattern 23d. The control wire 61a has a connector 63-1 that is at the middle of the control wire 61a. The connector 63-1 is fixed to the control electrode G-1. The connector 63-1 constitutes a stitch. In other words, the control electrode G-1, the control electrode G-3, and the conductive pattern 23d are electrically connected to each other by stitch bonding.

The control wire 61b is a wire 60 for electrically connecting the control electrode G-2 of the semiconductor chip 30-2 and the control electrode G-4 of the semiconductor chip 30-4 to the conductive pattern 23d. The control wire 61b is fixed to the control electrode G-2 and the control electrode G-4. The control wire 61b is apart from the peripheral edge Lx2 of the wiring member 40 in the X2 direction. The control wire 61b extends along the peripheral edge Lx2 in the direction of the Y-axis. In other words, in plan view, the control wire 61b is separate from the wiring member 40.

The control wire 61b has a connector 64-4 that is one end of the control wire 61b in the Y1 direction. The connector 64-4 is fixed to the control electrode G-4. The control wire 61b has a connector 64 that is the other end of the control wire 61b. The connector 64 is fixed to the conductive pattern 23d. The control wire 61b has a connector 64-2 that is at the middle of the control wire 61b. The connector 64-2 is fixed to the control electrode G-2. The connector 64-2 constitutes a stitch. In other words, the control electrode G-2, the control electrode G-4, and the conductive pattern 23d are electrically connected to each other by stitch bonding.

The auxiliary wire 62a is a wire 60 for electrically connecting the main electrode E-1 of the semiconductor chip 30-1 to the conductive pattern 23c. The auxiliary wire 62a is fixed to the main electrode E-1. Specifically, the auxiliary wire 62a is an auxiliary emitter terminal for precisely controlling voltage between the control electrode G-1 and the main electrode E-1. The auxiliary wire 62a is an example of a “first auxiliary wire.”

In plan view, the auxiliary wire 62a extends in the direction of the Y-axis. The auxiliary wire 62a has a connector 65-1 that is one end of the auxiliary wire 62a in the Y1 direction. The connector 65-1 is fixed to the main electrode E-1. The auxiliary wire 62a has a connector 65 that is the other end of the auxiliary wire 62a. The connector 65 is fixed to the conductive pattern 23c. In plan view, the connector 65-1 is disposed inside the notch 43a. Thus, in plan view, the auxiliary wire 62a is separate from the wiring member 40. As will be understood from the above description, the notch 43a corresponds to a point (connector 65-1) at which the main electrode E-1 and the auxiliary wire 62a are fixed to each other. The notch 43a is an example of a “first notch.”

The auxiliary wire 62b is a wire 60 for electrically connecting the main electrode E-2 of the semiconductor chip 30-2 to the conductive pattern 23c. The auxiliary wire 62b is fixed to the main electrode E-2. Specifically, the auxiliary wire 62b is an auxiliary emitter terminal for precisely controlling voltage between the control electrode G-2 and the main electrode E-2. The auxiliary wire 62b is an example of a “second auxiliary wire.”

In plan view, the auxiliary wire 62b extends in the direction of the Y-axis. The auxiliary wire 62b has a connector 66-2 that is one end of the auxiliary wire 62b in the Y1 direction. The connector 66-2 is fixed to the main electrode E-2. The auxiliary wire 62b has a connector 66 that is the other end of the auxiliary wire 62b. The connector 66 is fixed to the conductive pattern 23c. In plan view, the connector 66-2 is disposed inside the notch 43b. Thus, in plan view, the auxiliary wire 62b is separate from the wiring member 40. As will be understood from the above description, the notch 43b corresponds to a point (connector 66-2) at which the main electrode E-2 and the auxiliary wire 62b are fixed to each other. The notch 43b is an example of a “second notch.”

As described above, in the first embodiment, the main electrodes E of the semiconductor chips 30 are electrically connected to the plate-shaped wiring member 40. Thus, compared to a configuration (hereinafter referred to as “comparative example”) in which each of the main electrodes E is connected to a linear wire 60, it is possible to reduce electrical resistance of current paths including the main electrodes E. Specifically, it is possible to reduce electrical resistance of the current path Pa and electrical resistance of the current path Pb. The current path Pa is a path from the semiconductor chip 30-1 and the semiconductor chip 30-3 to the conductive pattern 23a. The current path Pb is a path from the semiconductor chip 30-2 and the semiconductor chip 30-4 to the conductive pattern 23b.

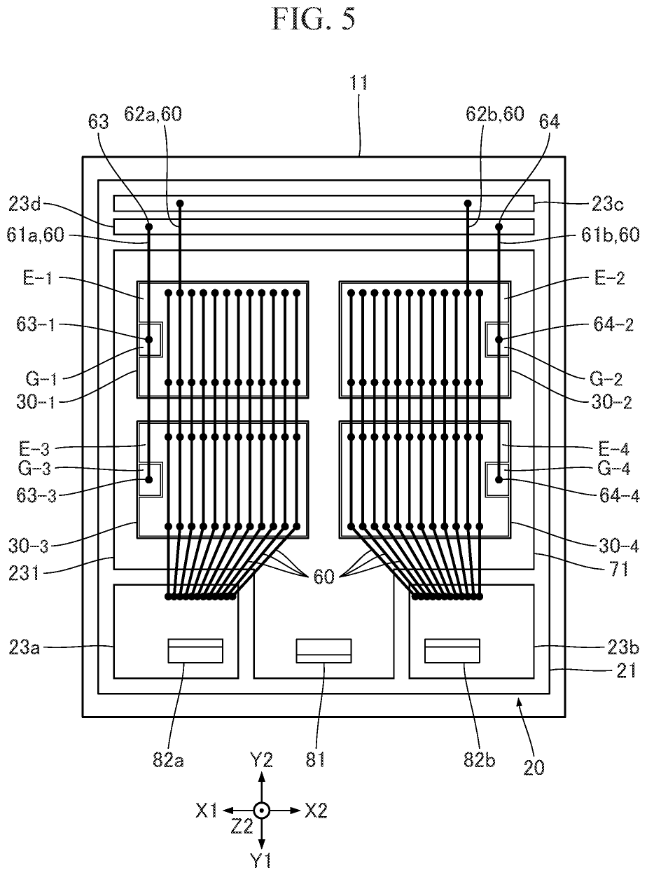

FIG. 5 is a plan view of the comparative example in which a plurality of wires 60 is used instead of the wiring member 40. As will be understood from FIG. 5, in the comparative example, a length of a wire 60, which connects the semiconductor chip 30-1 and the conductive pattern 23a to each other, is different from a length of another wire 60, which connects the semiconductor chip 30-3 and the conductive pattern 23a to each other, for example. In other words, electrical resistance of a current path from the semiconductor chip 30-1 to the conductive pattern 23a is different from electrical resistance of a current path from the semiconductor chip 30-3 to the conductive pattern 23a. In the first embodiment, the semiconductor chip 30-1 and the semiconductor chip 30-3 are connected to the conductive pattern 23a via the plate-shaped wiring member 40. Thus, electrical resistance of a current path from the semiconductor chip 30-1 to the conductive pattern 23a and electrical resistance of a current path from the semiconductor chip 30-3 to the conductive pattern 23a are less than those of the comparative example. As a result, it is possible to reduce a difference between electrical resistance of the current path from the semiconductor chip 30-1 to the conductive pattern 23a and electrical resistance of the current path from the semiconductor chip 30-3 to the conductive pattern 23a. In other words, according to the first embodiment, it is possible to reduce a difference in electrical resistance between current paths including the main electrodes E.

In the comparative example, a plurality of wires 60, which electrically connect the semiconductor chip 30-3 to the conductive pattern 23a, are different from each other in length. In other words, the plurality of wires 60 are different from each other in electrical resistance. Thus, a long wire 60 among the plurality of wires 60 generates heat greater than heat generated by a short wire 60 among the plurality of wires 60. As a result, a part of the plurality of wires 60 may generate heat excessively. In contrast to the comparative example, in the first embodiment, the main electrodes E of the semiconductor chips 30 are electrically connected to the plate-shaped wiring member 40. Thus, according to the first embodiment, it is possible to reduce a difference in electrical resistance between the current paths (Pa, Pb) including the main electrodes E.

The top surface T-1 has a region that is apart from the center of the top surface T-1 in the X1 direction, and the control electrode G-1 is disposed on the region of the top surface T-1. The top surface T-2 has a region that is apart from the center of the top surface T-2 in the X2 direction, and the control electrode G-2 is disposed on the region of the top surface T-2. In other words, the semiconductor chip 30-1 and the semiconductor chip 30-2 are aligned with each other to be the first row. The control electrode G-1 is disposed on one end of the first row. The control electrode G-2 is disposed on the other end of the first row. The semiconductor chip 30-3 and the semiconductor chip 30-4 are aligned with each other to be the second row. The control electrode G-3 is disposed on one end of the second row. The control electrode G-4 is disposed on the other end of the second row. Thus, an advantage can be obtained in that the control wire 61a and the control wire 61b are readily disposed so as not to interfere with the wiring member 40.

In the first embodiment, the control electrode G-n is separate from the wiring member 40 in plan view. Thus, the advantage is significant in that the control wire 6la and the control wire 61b are readily disposed so as not to interfere with the wiring member 40. The control electrode G-1 and the control electrode G-3 are spaced apart from the wiring member 40 in the X1 direction. Thus, it is easy to dispose the control wire 61a so as not to interfere with the wiring member 40. The control electrode G-2 and the control electrode G-4 are spaced apart from the wiring member 40 in the X2 direction. Thus, it is easy to dispose the control wire 61b so as not to interfere with the wiring member 40. In plan view, part or all of the control electrode G-n may overlap the wiring member 40.

In the first embodiment, the wiring member 40 includes the notch 43a and the notch 43b. Thus, it is easy to fix the auxiliary wire 62a and the auxiliary wire 62b to the main electrode E-1 and the main electrode E-2, respectively.

The height H of each of the semiconductor chips 30 is changed dependent on the type of the semiconductor module 100 (for example, rated voltage). Thus, in a case in which wiring members 40 of the same shape are used for semiconductor modules 100 of different types, a distance between a cover 41 and semiconductor chips 30 in a semiconductor module 100 may be changed depending on the type of the semiconductor module 100. In the first embodiment, the conductive spacer 50-n is interposed between the main electrode E-n and the wiring member 40. Thus, selecting an appropriate thickness S of each of the conductive spacers 50 enables wiring members 40 of the same shape to be used for different types of semiconductor modules 100 that each have a different height H of the semiconductor chip 30-n.

### B: Second Embodiment

A second embodiment of the present disclosure will be described. In the descriptions of the following embodiments, elements having the same functions as in the first embodiment are denoted by the same reference numerals used for like elements in the description of the first embodiment, and detailed description thereof is omitted, as appropriate.

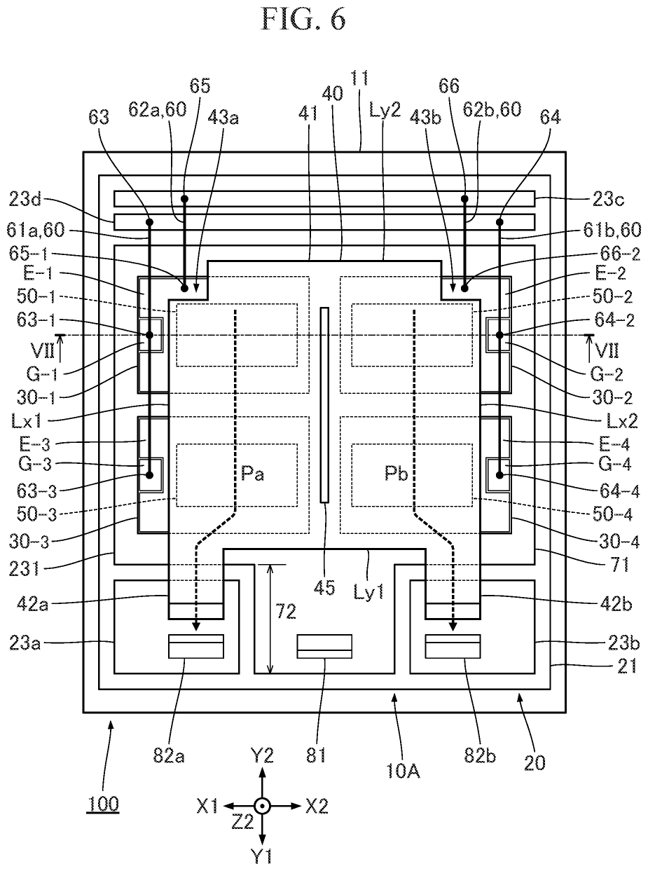

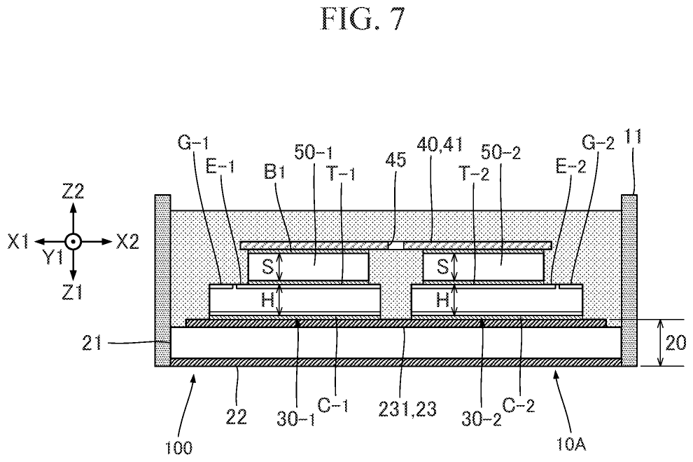

FIG. 6 is a plan view of the semiconductor module 100 according to the second embodiment. FIG. 7 is a cross section taken along line VII-VII in FIG. 6. In the second embodiment, the semiconductor module 100 includes a semiconductor unit 10A shown in FIG. 6 instead of the semiconductor unit 10 in the first embodiment.

As shown in FIG. 6 and FIG. 7, in the second embodiment, the wiring member 40 of the semiconductor unit 10A has a through hole 45. Specifically, the cover 41 of the wiring member 40 has the through hole 45. The second embodiment has the same configuration as that of the first embodiment, except that the wiring member 40 has the through hole 45. Thus, the second embodiment provides the same effects as those provided by the first embodiment.

The through hole 45 is an opening passing through the wiring member 40. In the second embodiment, the through hole 45 has an elongated shape along the Y-axis. Specifically, the through hole 45 extends in the direction of the Y-axis on a middle portion of the cover 41 of the wiring member 40 in the direction of the X-axis. In other words, the wiring member 40 has a region interposed between a first line, which is a line of the semiconductor chip 30-1 and the semiconductor chip 30-3, and a second line, which is a line of the semiconductor chip 30-2 and the semiconductor chip 30-4. The through hole 45 is formed on the region of the wiring member 40. Thus, in plan view, the through hole 45 is separate from the four semiconductor chips 30-1 to 30-4. As will be understood from the above description, the through hole 45 extends not only along the current path Pa, but also along the current path Pb.

The encapsulant 12 is formed in a process (hereinafter referred to as an “encapsulating process”) in which a liquid resin material is filled into the inside of the housing 11 and then the resin material is cured. In the encapsulating process, foam may form in the resin material. In the configuration in which the wiring member 40 is disposed, the foam having formed in the encapsulating process may remain under the wiring member 40. The foam, which remains under the wiring member 40, causes a decrease in electrical insulation of the wiring member 40. In the second embodiment, the foam having formed in the encapsulating process is discharged upward through the through hole 45. In other words, probability decreases that foam will remain under the wiring member 40. Thus, it is possible to substantially prevent a decrease in electrical insulation due to foam in the encapsulant 12.

In a configuration in which the through hole 45 has an elongated shape along the X-axis, the through hole 45 limits not only a width of the current path Pa extending from the semiconductor chip 30-1 and the semiconductor chip 30-3 to the conductive pattern 23a, but also a width of the current path Pb extending from the semiconductor chip 30-2 and the semiconductor chip 30-4 to the conductive pattern 23b. In the second embodiment, the through hole 45 has an elongated shape along the Y1 direction. Thus, it is possible to reduce effects of the through hole 45 on the current path Pa and on the current path Pb. As a result, it is possible to substantially prevent an increase in electrical resistance of each of the current paths Pa and Pb and to reduce form that remains in the encapsulant 12.

### C: Third Embodiment

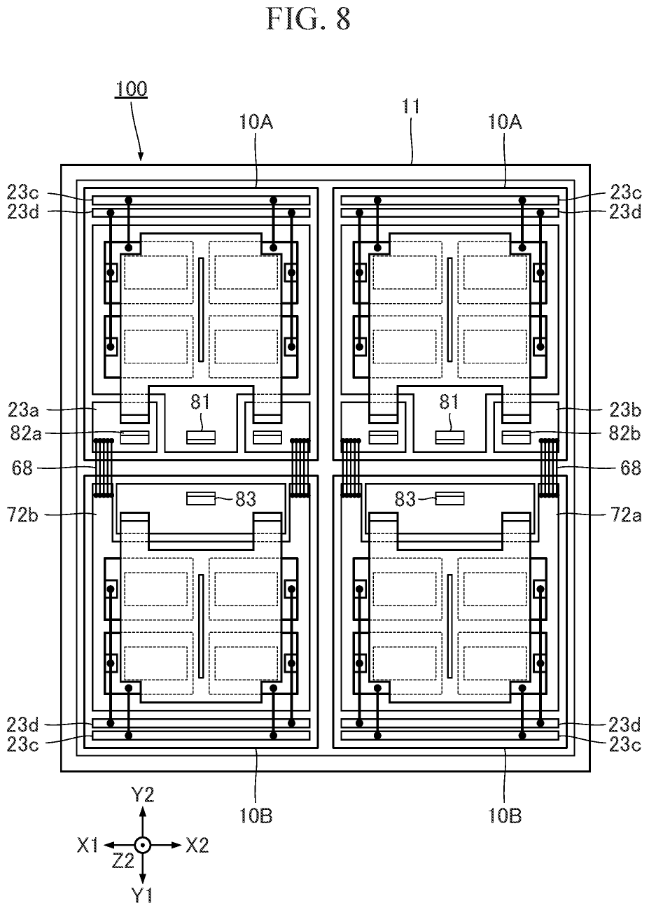

FIG. 8 is a plan view of the semiconductor module 100 according to a third embodiment. As shown in FIG. 8, in the third embodiment, the semiconductor module 100 includes two semiconductor units 10A, two semiconductor units 10B, the housing 11, and the encapsulant 12. The housing 11 accommodates the two semiconductor units 10A and the two semiconductor units 10B. The encapsulant 12 is made of an insulating material filled in the internal space the housing 11. In FIG. 8, the encapsulant 12 is omitted for convenience.

The two semiconductor units 10A are aligned with each other along the X-axis. The two semiconductor units 10B are aligned with each other along the X-axis. The two semiconductor units 10B are spaced apart from the two semiconductor units 10A in the Y1 direction. The two semiconductor units 10A constitute an upper arm of an inverter circuit. The two semiconductor units 10B constitute a lower arm of the inverter circuit. Each of the two semiconductor units 10A has the same configuration as that of the semiconductor unit 10A in the second embodiment.

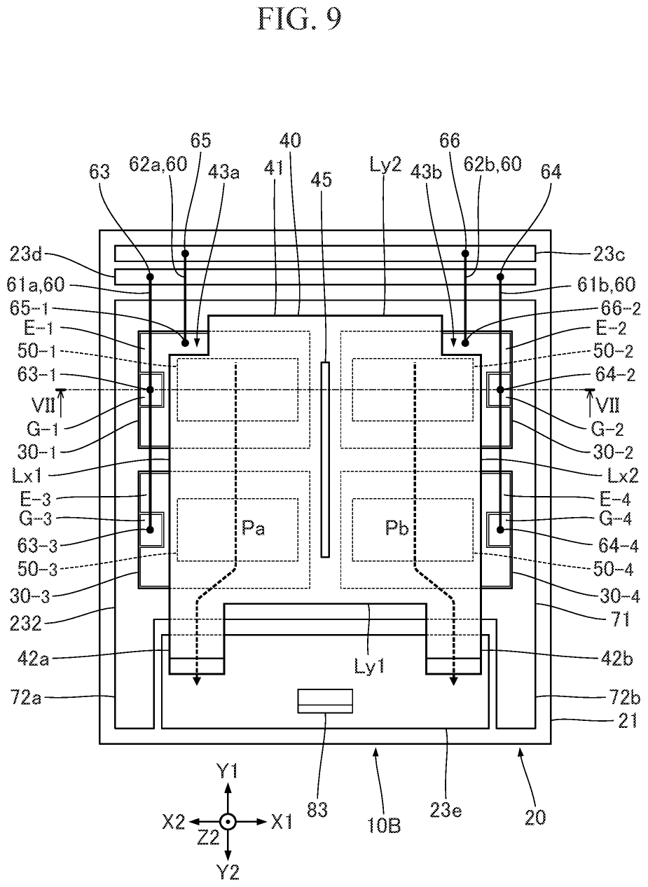

FIG. 9 is a plan view of a semiconductor unit 10B. In FIG. 9, the X-axis, the Y-axis, and the Z-axis are defined that are perpendicular to one another. In FIG. 9, the direction of the X-axis (X1 direction and X2 direction) is opposite to that shown in FIG. 1. In FIG. 9, the direction of the Y-axis (Y1 direction and Y2 direction) is opposite to that shown in FIG. 1.

As shown in FIG. 9, the shapes of the plurality of conductive patterns 23 of the semiconductor unit 10B are different from those of the semiconductor unit 10A. Specifically, the semiconductor unit 10B includes a conductive pattern 232 and a conductive pattern 23e instead of the conductive pattern 231, the conductive pattern 23a, and the conductive pattern 23b of the semiconductor unit 10A.

The conductive pattern 232 includes the mounting portion 71, a connection portion 72a, and a connection portion 72b. As in the first embodiment, in plan view, the mounting portion 71 is substantially rectangular. The mounting portion 71 has a first end portion in the X2 direction. The connection portion 72a protrudes in the Y2 direction from the first end portion of the mounting portion 71. The mounting portion 71 has a second end portion in the X1 direction. The connection portion 72b protrudes in the Y2 direction from the second end portion of the mounting portion 71. The conductive pattern 23e is interposed between the connection portion 72a and the connection portion 72b. The conductive pattern 23e is fixed to a connection terminal 83. The connection terminal 83 is a terminal for electrically connecting the semiconductor unit 10B to an external device.

The other elements of the semiconductor unit 10B are the same as those of the semiconductor unit 10A. For example, the wiring member 40 of the semiconductor unit 10A and the wiring member 40 of the semiconductor unit 10B are equal to each other in shape.

As shown in FIG. 8, the two semiconductor units 10A are disposed such that the conductive pattern 23c and the conductive pattern 23d are disposed in the Y2 direction. In contrast, the two semiconductor units 10B are disposed such that the conductive pattern 23c and the conductive pattern 23d are disposed in the Y1 direction. The conductive pattern 23a of the semiconductor unit 10A and the connection portion 72b of the semiconductor unit 10B are electrically connected to each other via a plurality of wires 68. The conductive pattern 23b of the semiconductor unit 10A and the connection portion 72a of the semiconductor unit 10B are electrically connected to each other via a plurality of wires 68.

In the above configuration, a power supply voltage of a high potential side is supplied to the connection terminal 81 of each of the semiconductor units 10A, whereas a power supply voltage of a low potential side is supplied to the connection terminal 83 of each of the semiconductor units 10B. The connection terminal 82a and the connection terminal 82b that are included in each of the semiconductor units 10A are each an output terminal for power output. The third embodiment provides the same effects as those provided by the first embodiment and by the second embodiment.

### D: Modifications

Specific modified modes that may be applied to each of the embodiments described above are described below. Two or more modifications freely selected from the following modifications may be combined as long as no conflict arises from such a combination.

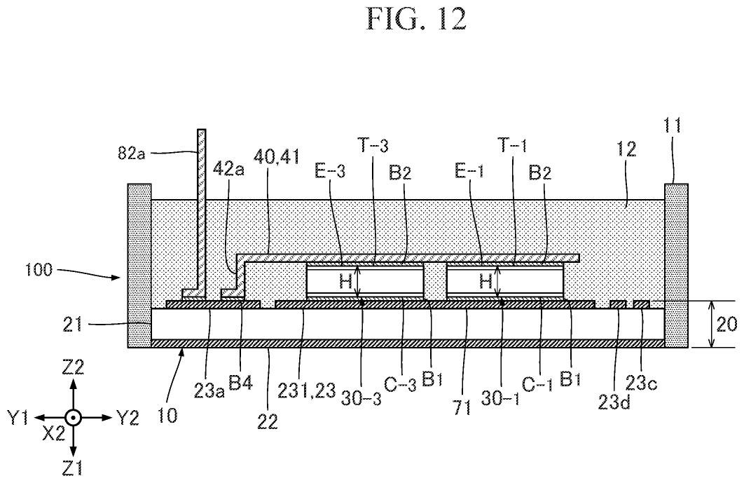

(1) In each embodiment described above, a configuration is described in which the conductive spacer 50-n is interposed between the wiring member 40 and the semiconductor chip 30-n. However, the conductive spacer 50-n may be omitted. For example, as shown in FIG. 12, the wiring member 40 and the semiconductor chip 30-n may be directly fixed to each other by a joining material B2 such as a solder material or a sintered material, without the conductive spacer 50-n. However, in the configuration in which the conductive spacer 50-n is not disposed, it is necessary to sufficiently separate the wiring member 40 from the peripheral edge of the semiconductor chip 30-n and from the conductive pattern 231 so as to maintain not only electrical insulation between the wiring member 40 and the peripheral edge of the semiconductor chip 30-n, but also electrical insulation between the wiring member 40 and the conductive pattern 231.

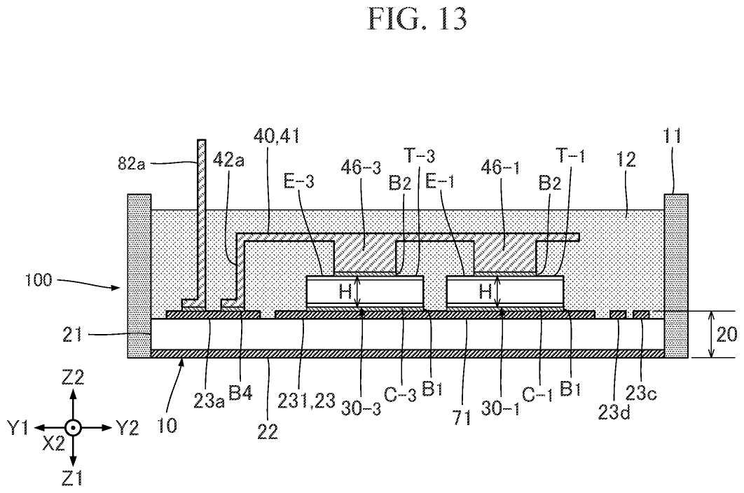

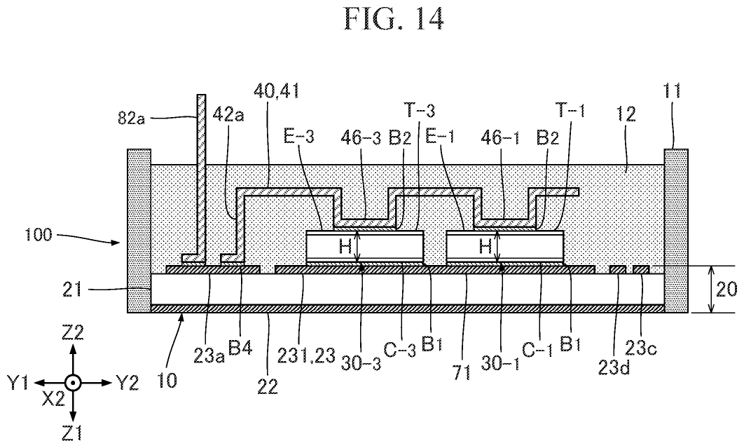

As shown in FIG. 13 and FIG. 14, the wiring member 40 may include protrusions 46 corresponding to the semiconductor chips 30. The protrusions 46 are used instead of the conductive spacers 50. The protrusions 46 include a protrusion 46-n corresponding to the semiconductor chip 30-n. The protrusion 46-n is disposed in a portion of the wiring member 40 (cover 41), the portion of the wiring member 40 overlapping the semiconductor chip 30-n in plan view. The protrusion 46-n protrudes in the Z1 direction from the lower surface of the cover 41 toward the semiconductor chip 30-n. In FIG. 13, the protrusion 46-n is thicker than another element (cover 41) of the wiring member 40. In FIG. 13, the protrusion 46-n is formed by, for example, a pressing process in which the plate-shaped wiring member 40 is bent.

(2) In each embodiment described above, a configuration is described in which the wiring member 40 includes the notch 43a and the notch 43b. However, the notch 43a and the notch 43b may be omitted. Foam, which has formed under the wiring member 40 in the encapsulating process, is discharged upward through the notch 43a or through the notch 43b. Thus, to prevent foam from remaining under the wiring member 40, it is preferable that the wiring member 40 include the notch 43a and the notch 43b.

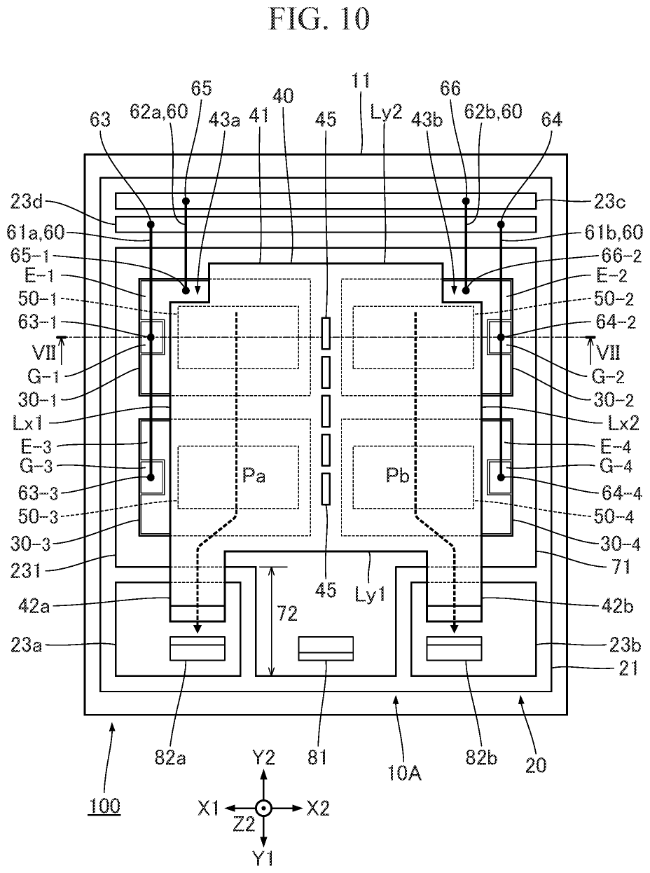

(3) The shape of the through hole 45 is not limited to that of each embodiment described above. For example, the through hole 45 may have a planar shape that is circular or rectangular. The wiring member 40 may have a plurality of through holes 45. For example, as shown in FIG. 10, the plurality of through holes 45 may be aligned with one another at intervals in the direction of the Y-axis.

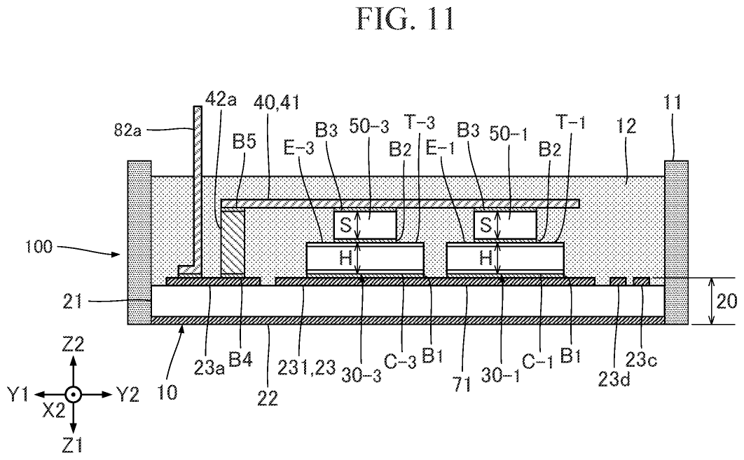

(4) In each embodiment described above, a configuration is described in which the wiring member 40 is the structure that includes the cover 41, the leg 42a, and the leg 42b that are integrally formed together with each other. However, as shown in FIG. 11, the leg 42a and the leg 42b may be formed separately from the cover 41. In FIG. 11, the leg 42a is a prismatic conductor. The leg 42a has a bottom surface that is fixed by the joining material B4 to the conductive pattern 23a. The leg 42a has a top surface that is fixed by a joining material B5, which has the same components as those of the joining material B4, to the cover 41. The leg 42b has a similar structure to that of the leg 42a. In the above description, the leg 42a and leg 42b are explained as elements of the wiring member 40. However, as will be understood from FIG. 11, the leg 42a and leg 42b may be understood as external elements different from the wiring member 40.

(5) In each embodiment described above, a configuration is described in which the four semiconductor chips 30-1 to 30-4 are of the same type. In the above configuration, the four semiconductor chips 30-1 to 30-4 are equal to each other in height H. Thus, the four conductive spacers 50-1 to 50-4 are equal to each other in thickness S. However, the four semiconductor chips 30-1 to 30-4 may not be of the same type. In other words, the four semiconductor chips 30-1 to 30-4 may not be equal to each other in height H. Thus, the four conductive spacers 50-1 to 50-4 may not be equal to each other in thickness S.

(6) In each embodiment described above, a configuration is described in which the semiconductor chip 30-n is an RC-IGBT. However, the semiconductor chip 30-n is not limited to an RC-IGBT. For example, the semiconductor chip 30-n may be an electronic element such as an insulated gate bipolar transistor (IGBT) or a Schottky Barrier Diode (SBD), etc. The semiconductor chip 30-n may be a metal oxide semiconductor field effect transistor (MOSFET) having a semiconductor layer made of a silicon (Si) material or of a silicon carbide (SiC) material. In a configuration in which the semiconductor chip 30-n is constituted of a MOSFET, the main electrode C-n is a drain electrode, whereas the main electrode E-n is a source electrode.

(7) In this disclosure, reference to an element using the designations “first,” “second,” etc., is used only for convenience in distinguishing elements, and has no substantive meaning. Thus, position of each of the element, order of manufacture of the elements, etc., are not limited by referring to an element using the designations “first,” “second,” etc.

### E: Supplemental Notes

The following configurations are derivable from the foregoing embodiments.

A semiconductor module according to one aspect (first aspect) of this disclosure is a semiconductor module including: a first semiconductor chip having a first top surface on which a first control electrode and a first main electrode are disposed; a second semiconductor chip having a second top surface on which a second control electrode and a second main electrode are disposed; and a plate-shaped wiring member facing the first main electrode and the second main electrode and being electrically connected to the first main electrode and to the second main electrode, in which the first semiconductor chip is spaced apart from the second semiconductor chip in a first direction in plan view, the first top surface has a first peripheral edge in the first direction, the first control electrode is interposed between the first peripheral edge of the first top surface and the first main electrode, the second top surface has a second peripheral edge in a second direction opposite to the first direction, and the second control electrode is interposed between the second peripheral edge of the second top surface and the second main electrode.

According to this aspect, the plate-shaped wiring member is electrically connected to the first main electrode of the first semiconductor chip and to the second main electrode of the second semiconductor chip. Thus, compared to a configuration in which the first main electrode and the second main electrode are connected to a linear wire, it is possible to reduce electrical resistance in a current path including the first main electrode or the second main electrode. It is possible to reduce a difference between electrical resistance of a current path including the first main electrode and electrical resistance of a current path including the second main electrode. The first top surface has a first region in the first direction. The first control electrode is disposed in the first region of the first top surface. The second top surface has a second region in the second direction. The second control electrode is disposed in the second region of the second top surface. In other words, the first control electrode and the second control electrode are disposed outside a line of the first semiconductor chip and the second semiconductor chip. Thus, an advantage can be obtained in that a wire for the first control electrode and a wire for the second control electrode are readily disposed so as not to interfere with the wiring member.

In a specific example (second aspect) of the first aspect, the first control electrode and the second control electrode are separate from the wiring member in plan view. According to this aspect, in plan view, the first control electrode and the second control electrode are separate from the wiring member. Thus, the advantage is significant in that a wire for the first control electrode and a wire for the second control electrode are readily disposed so as not to interfere with the wiring member.

In a specific example (third aspect) of the first aspect or of the second aspect, the semiconductor module further includes: a first auxiliary wire fixed to the first main electrode; and a second auxiliary wire fixed to the second main electrode, in which the wiring member includes: a first notch corresponding to a point at which the first main electrode and the first auxiliary wire are fixed to each other, and a second notch corresponding to a point at which the second main electrode and the second auxiliary wire are fixed to each other. According to this aspect, the wiring member includes the first notch and the second notch. Thus, it is easy to fix the first auxiliary wire and the second auxiliary wire to the first main electrode and the second main electrode, respectively.

In a specific example (fourth aspect) of any one of the first to third aspects, the semiconductor module further include: a first conductive spacer interposed between the first main electrode and the wiring member, and a second conductive spacer interposed between the second main electrode and the wiring member. According to the above aspects, selecting an appropriate thickness of the first conductive spacer and an appropriate thickness of the second conductive spacer enables wiring members of the same shape to be used for different types of semiconductor modules that each include both a first semiconductor chip having a different height from those of other first semiconductor chips and a second semiconductor chip having a different height from those of other second semiconductor chips. In addition, the first conductive spacer is interposed between the first main electrode and the wiring member, while the second conductive spacer is interposed between the second main electrode and the wiring member. Thus, the wiring member is sufficiently spaced apart from a peripheral edge of each of the first semiconductor chip and the second semiconductor chip, or from a mounting surface (for example, a conductive pattern) on which the first semiconductor chip and the second semiconductor chip are disposed. As a result, an advantage can be obtained in that the wiring member is electrically isolated readily from the peripheral edge of each of the first semiconductor chip and the second semiconductor chip, or from the mounting surface on which the first semiconductor chip and the second semiconductor chip are disposed.

In a specific example (fifth aspect) of the fourth aspect, the first semiconductor chip and the second semiconductor chip are equal to each other in height, and the first conductive spacer and the second conductive spacer are equal to each other in size. According to this aspect, the first conductive spacer and the second conductive spacer are equal to each other in size. Thus, there is no need to distinguish between the first conductive spacer and the second conductive spacer in a process of manufacturing the semiconductor module. As a result, it is possible to simplify control of the first conductive spacer and the second conductive spacer, thereby reducing manufacturing costs of the semiconductor module.

In a specific example (sixth aspect) of any one of the first to fifth aspects, the semiconductor module further includes an encapsulant encapsulating the first semiconductor chip, the second semiconductor chip, and the wiring member, in which the wiring member has a through hole. The encapsulant is formed in an encapsulating process in which a liquid resin material is filled into the inside of the housing and then the resin material is cured. In the encapsulating process, foam may form in the resin material. In the configuration in which the wiring member is disposed, the foam having formed in the encapsulating process may remain under the wiring member. The foam, which remains under the wiring member, causes a decrease in electrical insulation of the wiring member. According to a configuration in which the wiring member has the through hole, foam having formed in the encapsulating process is discharged upward through the through hole. In other words, the probability that the foam will remain under the wiring member decreases. Thus, it is possible to reduce the risk of a decrease in electrical insulation due to foam in the encapsulant.

In a specific example (seventh aspect) of any one of the first to fifth aspects, the semiconductor module further includes: a third semiconductor chip having a third top surface on which a third control electrode and a third main electrode are disposed; and a fourth semiconductor chip having a fourth top surface on which a fourth control electrode and a fourth main electrode are disposed, in which the third semiconductor chip is spaced apart from the first semiconductor chip in a third direction in plan view, the fourth semiconductor chip is spaced apart from the second semiconductor chip in the third direction in plan view, the third direction is perpendicular to the first direction and to the second direction, and the wiring member faces the third main electrode and the fourth main electrode and is electrically connected to the third main electrode and to the fourth main electrode. According to this aspect, the plate-shaped wiring member is electrically connected to the third main electrode of the third semiconductor chip and to the fourth main electrode of the fourth semiconductor chip, in addition to the first main electrode and to the second main electrode. Thus, compared to a configuration in which the third main electrode and the fourth main electrode are connected to a linear wire, it is possible to reduce electrical resistance in a current path including the third main electrode or the fourth main electrode. It is possible to reduce a difference between electrical resistance of a current path including the third main electrode and electrical resistance of a current path including the fourth main electrode.

In a specific example (eighth aspect) of the seventh aspect, the third top surface has a third peripheral edge in the first direction, the third control electrode is interposed between the third peripheral edge of the third top surface and the third main electrode, the fourth top surface has a fourth peripheral edge in the second direction, and the fourth control electrode is interposed between the fourth peripheral edge of the fourth top surface and the fourth main electrode. According to this aspect, the third control electrode and the fourth control electrode are disposed outside a line of the third semiconductor chip and the fourth semiconductor chip. Thus, an advantage can be obtained in that a wire for the third control electrode and a wire for the fourth control electrode are readily disposed so as not to interfere with the wiring member.

In a specific example (ninth aspect) of the eighth aspect, the semiconductor module further includes: a first control wire fixed to the first control electrode and to the third control electrode, and a second control wire fixed to the second control electrode and to the fourth control electrode. According to this aspect, the first control electrode and the third control electrode are spaced apart from the wiring member in the first direction. Thus, it is easy to dispose the first control wire so as not to interfere with the wiring member. Similarly, the second control electrode and the fourth control electrode are spaced apart from the wiring member in the second direction. Thus, it is easy to dispose the second control wire so as not to interfere with the wiring member.

In a specific example (tenth aspect) of any one of the seventh to ninth aspects, the semiconductor module further includes: an insulating substrate; a first conductive pattern disposed on the insulating substrate; and a second conductive pattern disposed on the insulating substrate, in which the first semiconductor chip, the second semiconductor chip, the third semiconductor chip, and the fourth semiconductor chip are fixed to the first conductive pattern, and the wiring member has an end in the third direction, the end of the wiring member being fixed to the second pattern. According to this aspect, a current from the first semiconductor chip, the second semiconductor chip, the third semiconductor chip, and the fourth semiconductor chip flows through the wiring member in the third direction, and then the current is supplied to the second conductive pattern from the end of the wiring member in the third direction. In other words, it is possible to reduce electrical resistance of a first current path and electrical resistance of a second current path, the first current path being a path from the first semiconductor chip and the third semiconductor chip to the second conductive pattern, the second current path being a path from the second semiconductor chip and the fourth semiconductor chip to the second conductive pattern.

In a specific example (eleventh aspect) of any one of the seventh to tenth aspects, the semiconductor module further includes an encapsulant encapsulating the first semiconductor chip, the second semiconductor chip, and the wiring member, the wiring member has a region interposed between a first line and a second line, the first line being a line of the first semiconductor chip and the third semiconductor chip, the second line being a line of the second semiconductor chip and the fourth semiconductor chip, and the region of the wiring member has a through hole that is elongated in the third direction. The encapsulant is formed in an encapsulating process in which a liquid resin material is filled into the inside of the housing, and then the resin material is cured. In the encapsulating process, foam may form in the resin material. In the configuration in which the wiring member is disposed, the foam having formed in the encapsulating process may remain under the wiring member. The foam, which remains under the wiring member, causes a decrease in electrical insulation of the wiring member. According to a configuration in which the wiring member has the through hole, foam having formed in the encapsulating process is discharged upward through the through hole. In other words, probability that the foam will remain under the wiring member decreases. Thus, it is possible to reduce a decrease in electrical insulation due to foam in the encapsulant.

In a configuration in which the through hole has an elongated shape along the first direction, the through hole limits a width of the first current path and a width of the second current path, the first current path extending from the first semiconductor chip and the second semiconductor chip in the third direction, the second current path extending from the second semiconductor chip and the fourth semiconductor chip in the third direction. According to a configuration in which the through hole has an elongated shape along the third direction, it is possible to reduce effects of the through hole on the first current path and on the second current path. As a result, it is possible to substantially prevent an increase in electrical resistance of each of the current paths and to reduce foam that remains in the encapsulant.

### DESCRIPTION OF REFERENCE SIGNS

100 . . . semiconductor module, 10, 10A, 10B . . . semiconductor unit, 11 . . . housing, 12 . . . encapsulant, 20 . . . mounting substrate, 21 . . . insulating substrate, 22 . . . metallic layer, 23, 231, 232, 23a, 23b, 23c, 23d, 23e . . . conductive pattern, 30-n (30-1, 30-2, 30-3, 30-4) . . . semiconductor chip, 40 . . . wiring member, 41 . . . cover, 42a, 42b . . . leg, 43a, 43b . . . notch, 45 . . . through hole, 46-n . . . protrusion, 50-n (50-1, 50-2, 50-3, 50-4) . . . conductive spacer, 60, 68 . . . wire, 61a, 61b . . . control wire, 62a, 62b . . . auxiliary wire, 71 . . . mounting portion, 72, 72a, 72b . . . connection portion, 81, 82a, 82b, 83 . . . connection terminal, Pa, Pb . . . current path.

What is claimed is:

1. A semiconductor module comprising:
a first semiconductor chip having a first top surface on which a first control electrode and a first main electrode are disposed;
a second semiconductor chip having a second top surface on which a second control electrode and a second main electrode are disposed; and
a plate-shaped wiring member facing the first main electrode and the second main electrode and being electrically connected to the first main electrode and to the second main electrode,
wherein the first semiconductor chip is spaced apart from the second semiconductor chip in a first direction in plan view,
wherein the first top surface has a first peripheral edge in the first direction,
wherein the first control electrode is interposed between the first peripheral edge of the first top surface and the first main electrode,
wherein the second top surface has a second peripheral edge in a second direction opposite to the first direction, and
wherein the second control electrode is interposed between the second peripheral edge of the second top surface and the second main electrode.

2. The semiconductor module according to claim 1, wherein the first control electrode and the second control electrode are separate from the wiring member in plan view.

3. The semiconductor module according to claim 1, further comprising:
a first auxiliary wire fixed to the first main electrode; and
a second auxiliary wire fixed to the second main electrode,
wherein the wiring member comprises:
a first notch corresponding to a point at which the first main electrode and the first auxiliary wire are fixed to each other, and
a second notch corresponding to a point at which the second main electrode and the second auxiliary wire are fixed to each other.

4. The semiconductor module according to claim 1, further comprising:
a first conductive spacer interposed between the first main electrode and the wiring member, and
a second conductive spacer interposed between the second main electrode and the wiring member.

5. The semiconductor module according to claim 4,
wherein the first semiconductor chip and the second semiconductor chip are equal to each other in height, and
wherein the first conductive spacer and the second conductive spacer are equal to each other in size.

6. The semiconductor module according to claim 1, further comprising
an encapsulant encapsulating the first semiconductor chip, the second semiconductor chip, and the wiring member,
wherein the wiring member has a through hole.

7. The semiconductor module according to claim 1, further comprising:
a third semiconductor chip having a third top surface on which a third control electrode and a third main electrode are disposed; and
a fourth semiconductor chip having a fourth top surface on which a fourth control electrode and a fourth main electrode are disposed,
wherein the third semiconductor chip is spaced apart from the first semiconductor chip in a third direction in plan view,
wherein the fourth semiconductor chip is spaced apart from the second semiconductor chip in the third direction in plan view,
wherein the third direction is perpendicular to the first direction and to the second direction, and
wherein the wiring member faces the third main electrode and the fourth main electrode and is electrically connected to the third main electrode and to the fourth main electrode.

8. The semiconductor module according to claim 7,
wherein the third top surface has a third peripheral edge in the first direction,
wherein the third control electrode is interposed between the third peripheral edge of the third top surface and the third main electrode,
wherein the fourth top surface has a fourth peripheral edge in the second direction, and
wherein the fourth control electrode is interposed between the fourth peripheral edge of the fourth top surface and the fourth main electrode.

9. The semiconductor module according to claim 8, further comprising:
a first control wire fixed to the first control electrode and to the third control electrode, and
a second control wire fixed to the second control electrode and to the fourth control electrode.

10. The semiconductor module according to claim 7, further comprising:
an insulating substrate;
a first conductive pattern disposed on the insulating substrate; and
a second conductive pattern disposed on the insulating substrate,
wherein the first semiconductor chip, the second semiconductor chip, the third semiconductor chip, and the fourth semiconductor chip are fixed to the first conductive pattern, and
wherein the wiring member has an end in the third direction, the end of the wiring member being fixed to the second pattern.

11. The semiconductor module according to claim 7, further comprising
an encapsulant encapsulating the first semiconductor chip, the second semiconductor chip, and the wiring member,
wherein the wiring member has a region interposed between a first line and a second line, the first line being a line of the first semiconductor chip and the third semiconductor chip, the second line being a line of the second semiconductor chip and the fourth semiconductor chip, and
wherein the region of the wiring member has a through hole that is elongated in the third direction.
